(19) United States
(12) Patent Application Publication
(10) Pub. No.: US 2022/0360047 A1
(43) Pub. Date: Nov. 10, 2022

(54) WIDE BANDWIDTH LASER CHIP

(71) Applicant: Microsoft Technology Licensing, LLC, Redmond, WA (US)

(72) Inventors: Pasi Petteri PIETILAE, Espoo (FI); Pietari TUOMISTO, Helsinki (FI); Simo Kaarlo Tapani TAMMELA, Espoo (FI)

(21) Appl. No.: 17/314,013

(22) Filed: May 6, 2021

(51) Int. Cl. H01S 5/12; H01S 5/22; H01S 5/026; H01S 5/40

(52) U.S. Cl. CPC H01S 5/1212; H01S 5/22; H01S 5/026; H01S 5/4031; H01S 5/4012

(57) ABSTRACT

A laser chip is described which comprises a plurality of gain areas. Each gain area comprises a ridge waveguide and a wavelength locking element, where the wavelength locking element in a gain area defines the output wavelength characteristics of visible light emitted from that gain area and adjacent gain areas comprise different wavelength locking elements.

### BACKGROUND

Head mounted displays and optical projectors include a light source which may include one or more LEDs or one or more lasers. LEDs and lasers have different characteristics and hence their use provides different advantages and disadvantages. For example, LEDs output light with a wide spectral bandwidth but are relatively inefficient. In comparison, the lasers are more efficient, but their output typically has a very narrow spectral bandwidth which can impair image quality (e.g. due to interference effects) and also the peak wavelength varies with temperature. The spectral bandwidth of a laser may be broadened by operating them in fast pulsed mode.

The embodiments described below are not limited to implementations which solve any or all of the disadvantages of known laser diodes.

### SUMMARY

The following presents a simplified summary of the disclosure in order to provide a basic understanding to the reader. This summary is not intended to identify key features or essential features of the claimed subject matter nor is it intended to be used to limit the scope of the claimed subject matter. Its sole purpose is to present a selection of concepts disclosed herein in a simplified form as a prelude to the more detailed description that is presented later.

A laser chip is described which comprises a plurality of gain areas. Each gain area comprises a ridge waveguide and a wavelength locking element, where the wavelength locking element in a gain area defines the output wavelength characteristics of visible light emitted from that gain area and adjacent gain areas comprise different wavelength locking elements.

Many of the attendant features will be more readily appreciated as the same becomes better understood by reference to the following detailed description considered in connection with the accompanying drawings.

### DESCRIPTION OF THE DRAWINGS

The present description will be better understood from the following detailed description read in light of the accompanying drawings, wherein:

FIGS. 1-3 show schematic diagrams of three examples of a laser chip having a wide spectral bandwidth;

FIG. 4 shows an example spectral output of a laser chip as shown in any of FIGS. 1-3;

FIG. 5 is a schematic diagram of an example grating-based structure;

FIGS. 6 and 7 show schematic diagrams of two further examples of a laser chip having a wide spectral bandwidth;

FIG. 8 shows an example spectral output of a laser chip as shown in any of FIGS. 6 and 7; and

FIGS. 9-12 show schematic diagrams of four more examples of a laser chip having a wide spectral bandwidth.

Like reference numerals are used to designate like parts in the accompanying drawings.

### DETAILED DESCRIPTION

The detailed description provided below in connection with the appended drawings is intended as a description of the present examples and is not intended to represent the only forms in which the present examples are constructed or utilized. The description sets forth the functions of the examples and the sequence of operations for constructing and operating the examples. However, the same or equivalent functions and sequences may be accomplished by different examples

Described herein is a laser chip having a wide spectral bandwidth in the visible light range. The laser chip comprises a plurality of gain areas which are integrally formed on the same substrate (i.e. the same wafer) as a single chip. Each gain area comprises a ridge waveguide (RWG) and a wavelength locking element Each wavelength locking element comprises a grating-based structure and different wavelength locking elements comprise different grating-based structures such that the wavelength profile of the output light from at least adjacent gain areas is different and in some examples, the wavelength profile of the light output from each gain area is different from all other gain areas in the laser chip. The wavelength profiles of the light output from each gain area are all in the visible part of the electromagnetic spectrum and in various examples, the wavelength profiles of the light output from each gain area in a single chip are all in the same color region of the visible spectrum (e.g. all in one of the yellow, red, green or blue regions of the visible spectrum) but at different (e.g. offset) wavelengths within that same color region (e.g. at wavelengths offset by 2 nm from each other).

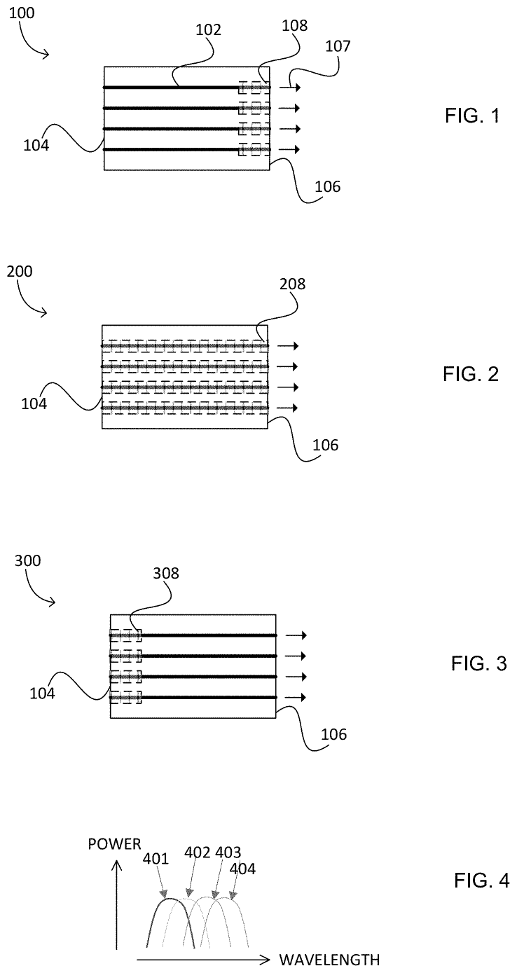

FIGS. 1-3 show schematic diagrams of three examples of a laser chip 100, 200, 300 having a wide spectral bandwidth in the visible light range. Each laser chip 100, 200, 300 comprises a plurality of gain areas, each comprising a RWG 102 that extends between the rear facet 104 and the front facet 106 of the chip. The gain areas (and hence the RWGs) are parallel to each other and in the examples shown they are equally spaced. A beam of light is emitted from the front facet 106 from each gain area, as indicated by the small arrows 107. The rear facet 104 may be coated with a dielectric to form a high reflectivity dielectric mirror (e.g. with a reflectivity back into the laser cavity of over 90%) and the front facet 106 may be coated with a dielectric to form a low reflectivity dielectric mirror.

Each gain area comprises a wavelength locking element 108, 208, 308 which uses a grating-based structure (and hence is frequency selective) and three different example implementations are shown in FIGS. 1-3. The wavelength locking is achieved as the grating reflects only part of the gain spectrum back into the active waveguide and the grating acts as a wavelength selective mirror. In all examples, the pitch of the grating is selected to provide wavelength locking at the desired wavelength and within any laser chip 100, 200, 300, the wavelength locking elements 108, 208, 308 differ for different gain areas (or regions) such that the wavelength profile of the output beams from different gain areas are different. For example, the centre wavelengths may be offset from each other by few nanometers, as shown schematically in FIG. 4, with different peaks 401-404 corresponding to the output from the different gain areas within the single laser chip 100, 200, 300. The gratings forming the wavelength locking elements 108, 208, 308 may be tuned to provide an output with a broader frequency range than a typical wavelength locked laser (e.g. of around 2 nm) that is centered on a predefined wavelength and where different wavelength locking elements 108, 208, 308 (in different gain areas within the same device) have different (e.g. offset) predefined center wavelengths.

In the example of FIG. 1, the wavelength locking elements 108 are positioned at the front facet 106 and extend (from the front facet 106 towards the rear facet 104) over only a short length of the gain area (e.g. they may extend over less than a half or less than a quarter of the length of the gain area, although this may depend upon the operating wavelength). The wavelength locking elements 108 are grating-based structures and form a wavelength-selective mirror which may be used in combination with the dielectric coating on the front facet described above (e.g. to prevent a second cavity being created between the grating and the front facet of the laser).

In the example of FIG. 2, the wavelength locking elements 208 extend over substantially the entire length of the gain area. Whilst this may mean that the gain regions resemble a DFB laser, the nature of the wavelength locking elements 208 are different. The aim of a DFB laser is to provide single frequency operation and hence the grating structure that extends along the entire length of the gain region is tuned to that single frequency operation. However, in the present invention (and as described above), the grating may be tuned to provide an output with a broader frequency range (e.g. of around 2 nm) that is centered on a predefined wavelength and where different wavelength locking elements 208 (in different gain areas) have different (e.g. offset) predefined center wavelengths.

In the example of FIG. 3, the wavelength locking elements 308 are positioned at the rear facet 104 and extend (from the rear facet 104 towards the front facet 106) over only a short length of the gain area. Whilst this may mean that the gain regions resemble a DBR laser, the nature of the wavelength locking elements 308 are different. The aim of a DBR laser is to provide single frequency operation and hence the grating (which is placed at the rear facet or at both the front and rear facets) is tuned to that single frequency operation. However, in the present invention, the grating is tuned to provide an output with a broader frequency range (e.g. of around 2 nm) that is centered on a predefined wavelength and where different wavelength locking elements 308 (in different gain areas) have different (e.g. offset) predefined center wavelengths.

In a further example, which is a variation on that shown in FIG. 1, the wavelength locking elements 108 may comprise a plurality of partially overlapping gratings and so whilst the wavelength locking elements 108 extend from the front facet 106 towards the rear facet 104, they may extend over a longer length than those in the example of FIG. 1. Each over the partially overlapping gratings within a wavelength locking element 108 may operate on (and hence generate as output) a different wavelength (or range of wavelengths centered on a different wavelength).

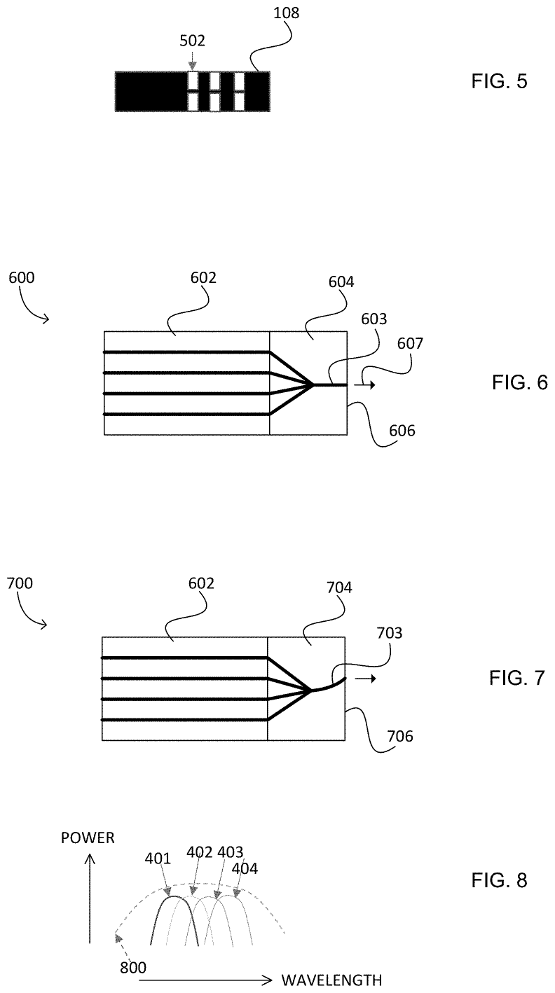

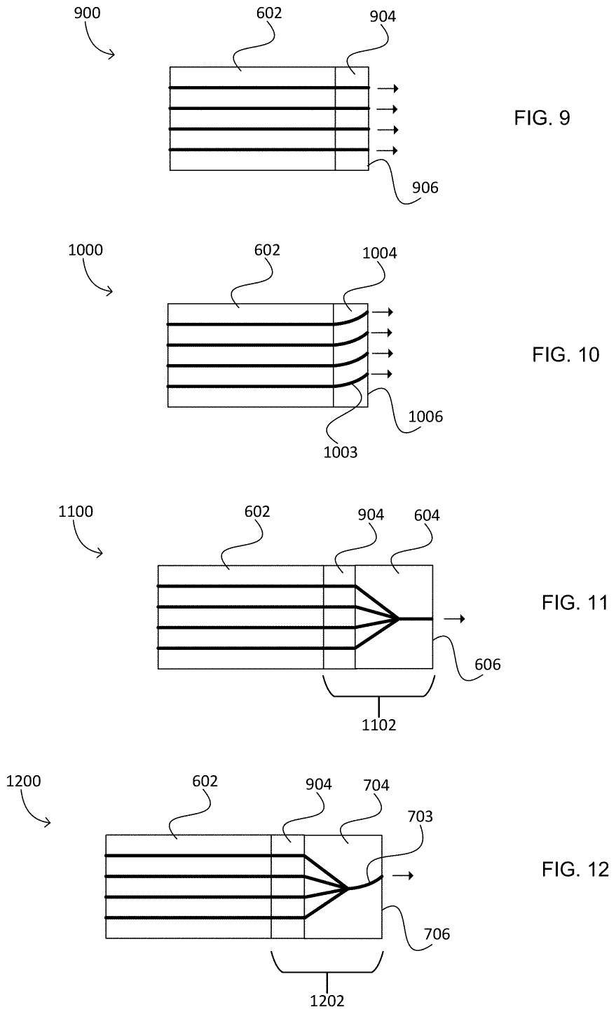

The grating-based structures which form the wavelength locking elements 108, 208, 308 may be formed in different ways and an example is shown in FIG. 5 (this corresponds to the example in FIG. 1, since the grating-based structure is only present adjacent to the front facet). In this example, the grating elements 502 are formed either side of the RWG. In other examples, the grating elements may extend across the entirety of the gain region (including under/over the RWG) or may only be present in the area of the RWG (e.g. under/over/within the RWG). In some examples the grating elements may be integrated into the epitaxial material (e.g. where the gratings are under the RWG).

By including multiple gain areas and wavelength locking elements 108, 208, 308 centered on different wavelengths within the visible spectrum (and in some examples, within the same color band of the visible spectrum) in the same laser chip, the resultant laser chip (which is a single element, formed together on the same wafer) has a broader output spectrum, as shown in FIG. 4. The use of different wavelength locking elements as described herein means that the differences in spectral output between adjacent gain areas can be achieved without requiring a complex re-growth of the epitaxial structure (e.g. without offsetting the quantum wells with epitaxy methods). The inclusion of the wavelength locking elements in each gain area also increases the stability of the spectral output (e.g. the stability of the center wavelength of the emitted light) over the range of operating temperatures.

In any of the examples described above, the grating-based structures may be chirped (i.e. such that the periodicity of the grating is not constant but changes over the length of the grating-based structure) to broaden the output wavelength range of the gain area.

Where such a laser chip is used in a head mounted display or projector system, the spectral broadening improves the projected image quality whilst still providing the improved operating efficiency (e.g. compared to using LEDs).

In the examples shown in FIGS. 1-3, there is one output beam from each gain region, as indicated by the arrows 107 and in each example, there are four gain regions and hence four output beams. It will be appreciated, however, that in other examples there may be fewer than four gain regions and hence output beams, (e.g. two gain regions, producing two output beams) or more than four gain regions (e.g. six gain regions, producing six output beams). By having the multiple gain regions in a single laser chip, the spacing between gain regions may be significantly smaller than if separate laser chips were used and this may simplify the subsequent optics in whatever display device (e.g. a head mounted display or projector system) the laser chip is used in.

In other examples, the plurality of outputs (one from each gain area) may be combined into a single output beam before being output from the laser chip. As shown in FIGS. 6 and 7, a (passive) combiner element 604, 704 may be integrally formed with the gain regions such that there is only a single output, as indicated by arrow 607 and this provides an output beam with a much wider spectral bandwidth 800 (e.g. compared to a single output beam from one gain region), as shown in FIG. 8. For example, if each of the four output beams 401-404 are approximately 2-3 nm wide, then a spectral bandwidth of the single combined output may be around 10 nm.

The integrated laser chips 600, 700 shown in FIGS. 6 and 7 each comprise a gain section 602 followed by a combiner section 604, 704 which is positioned adjacent to where the front facet 106 of the gain section would otherwise be. The gain section 602 may be as shown in any of FIGS. 1-3, e.g. gain section 100 from FIG. 1 with the wavelength locking elements 108 at the front facet, gain section 200 from FIG. 2 with the wavelength locking elements 208 extending along substantially the entire RWG, or gain section 300 from FIG. 3 with the wavelength locking elements 308 at the rear facet. The combiner section 604, 704 comprises a plurality of input waveguides with one input waveguide which extends from (or is connected to) the RWG of each gain region in the gain section 602 and these join together to become a single output waveguide 603, 703. It will be appreciated that the waveguide shapes within the combiner section 604, 704 are not shown precisely in FIGS. 6 and 7 because when implemented any changes in direction will be gradual and curved, rather than abrupt.

In order to avoid a secondary cavity within the integrated laser chips 600, 700, the front facet 606 of the laser chip 600 may be angled or have an antireflective coating. In addition or instead, the single output waveguide 703 within the combiner element 704 may be angled as it approaches the front facet 706, as shown in FIG. 7.

Instead of integrally forming a gain section 602 and a passive combiner section 604, 704 (as shown in FIGS. 6 and 7), the laser chip 900, 1000 may comprise an integrally formed gain section 602 followed by a gain/modulator section 904, 1004 which is positioned adjacent to where the front facet 106 of the gain section would otherwise be. The gain section 602 may be as shown in any of FIGS. 1-3, e.g. gain section 100 from FIG. 1 with the wavelength locking elements 108 at the front facet, gain section 200 from FIG. 2 with the wavelength locking elements 208 extending along substantially the entire RWG, or gain section 300 from FIG. 3 with the wavelength locking elements 308 at the rear facet.

The gain/modulator section 904, 1004 is an active section (unlike the combiner sections 604, 704) which provides gain and/or modulation of the input light (e.g. the light output by the gain section 602). The gain/modulator section 904, 1004 is electrically isolated (within the laser chip 900, 1000) from the gain section 602, to provide independent control. The control of the part of the gain/modulator section 904, 1004 that relates to each gain portion (e.g. each RWG) in the gain section 602 may be independent, so that the gain/modulation can be independently controlled for each output beam, or there may be only common controls for the gain/modulator section 904, 1004 such that each output beam undergoes gain/modulation in the same way within the gain/modulator section 904, 1004.

In order to avoid a secondary cavity within the integrated laser chips 900, 1000, the front facet 906 of the laser chip 900 may be angled or have an antireflective coating. In addition or instead, the waveguides 1003 within the gain/modulator section 1004 may be angled as they approach the front facet 1006, as shown in FIG. 10.

By incorporating a gain/modulator section 904, 1004 into the integrated laser chip 900, 1000, it is possible to increase the dynamic range of the laser chip (e.g. to increase the range of output powers that can be provided), improve efficiency and performance and reduce the complexity of the drive/control circuitry. For example, to obtain a large range of output powers from a laser chip without an integrated gain/modulator section 904, 1004, it may be necessary to both operate it close to threshold (to obtain low output powers) and at higher drive currents. When operating at higher drive currents, there may be thermal issues which impact the laser performance (e.g. which result in a wavelength shift and/or non-linear output powers). To obtain low output powers, it may be necessary to operate very close to the threshold; however, the threshold may shift with temperature. The wavelength shift is addressed through the use of the wavelength locking elements 108, 208, 308 (as described above) and through the use of an integrated gain/modulator section 904, 1004 the control of the output power may be decoupled from the control of the gain section 602 and hence provide more stable and predictable operation (e.g. because the performance of the gain/modulator section 904, 1004 is more stable over a wide range of both output powers and operating temperatures compared to the gain section 602). High dynamic ranges may be important where the laser chip is used in a head mounted display that must operate both in low light levels (e.g. in a dark room) and high light levels (e.g. in daylight).

In further examples, the integrated laser chip 1100, 1200 may comprise both a combiner section 604, 704 and a gain/modulator section 904, 1004 as shown in FIGS. 11 and 12. In the examples shown in FIGS. 12 and 13, the combiner section and gain/modulator section are two discrete sections (formed within the same device), with the gain/modulator section adjacent to the gain section 602 (e.g. to provide individual gain/modulation control per beam generated by the gain section 602) with the combiner section at the output of the gain/modulator section. In other examples, the two sections may be integrated into a single section 1102, 1202 and/or the combiner section may be adjacent to the gain section 602 and the gain/modulator section at the output of the combiner section (e.g. such that the broader output spectrum 800 is collectively amplified/modulated by the gain/modulator section).

By integrating forming a gain section 602 with a combiner section and/or a gain/modulator section, the need for external components is reduced (e.g. external combiners, amplifiers and/or modulators) and this alleviates coupling difficulties (i.e. by integrally forming the different sections, the waveguides are inherently aligned and so there is inherently good coupling from one section to another).

The laser chip described herein is formed as a single entity on a substrate (or wafer) where the nature of the substrate may depend upon the operating wavelength of the laser chip. For example, a laser chip operating in the blue or green wavelength bands may be formed from gallium nitride whereas a laser chip operating in the red wavelength band may be formed form gallium arsenide.

As described above, the spectral bandwidth of a laser may be increased by operating it in pulse mode. The laser chips described herein may be operated in pulse mode to further broaden their spectral bandwidth.

The laser chip described herein may be used in many different applications. For example, the laser chip may be used within a head mounted display or laser projector. A head mounted display or laser projector may comprise a plurality of laser chips as described herein, e.g. one (or more) operating in the red wavelength band (with each of the individual gain regions centered on a different wavelength within that band), one (or more) operating in the green wavelength band (with each of the individual gain regions centered on a different wavelength within that band) and one (or more) operating in the blue wavelength band (with each of the individual gain regions centered on a different wavelength within that band).

Although the present examples are described and illustrated herein as being implemented in a head mounted display or laser projector system, the system described is provided as an example and not a limitation. As those skilled in the art will appreciate, the present examples are suitable for application in a variety of different types of optical systems.

A first further example provides a laser chip comprising a plurality of gain areas, each gain area comprising a ridge waveguide and a wavelength locking element, wherein each wavelength locking element defines output wavelength characteristics of visible light emitted from the gain area and adjacent gain areas comprise different wavelength locking elements.

In the laser chip of the first further example, each of the plurality of gain areas may comprise a different wavelength locking element, such that for each gain area, the output wavelength characteristics of visible light emitted from the gain area is different. The output wavelength characteristics of visible light emitted from each gain area may be offset by a predefined amount.

In the laser chip of the first further example, the wavelength locking element in each gain area may be proximate to a front facet of the gain area.

In the laser chip of the first further example, the wavelength locking element in each gain area may extend over substantially the entire length of the gain area.

In the laser chip of the first further example, the wavelength locking element in each gain area may be proximate to a rear facet of the laser chip.

In the laser chip of the first further example, the wavelength locking element may be a grating-based structure. The grating-based structure may comprise a chirped grating.

The laser chip of the first further example may further comprise an integrally formed combiner section, the combiner section comprising a plurality of input waveguides, each input waveguide coupled to the ridge waveguide in one of the gain areas and a single output waveguide.

The laser chip of the first further example may further comprise an integrally formed gain/modulation section, the gain/modulation section comprising a plurality of waveguides, each waveguide coupled to the ridge waveguide in one of the gain areas.

The laser chip of the first further example may further comprise an integrally formed combiner section and an integrally formed gain/modulation section, the combiner section comprising a plurality of input waveguides, each input waveguide coupled directly or indirectly to the ridge waveguide in one of the gain areas and a single output waveguide. Each input waveguide in the combiner section may be coupled to the ridge waveguide in one of the gain areas via the gain/modulation section.

The laser chip of the first further example may comprise four gain areas.

In the laser chip of the first further example, the ridge waveguides in each of the plurality of gain areas may be parallel to each other.

A second further example provides a head mounted display comprising one or more laser chips of the first further example.

A third further example provides a head mounted display comprising one or more laser chips, each laser chip comprising a plurality of gain areas, each gain area comprising a ridge waveguide and a wavelength locking element, wherein each wavelength locking element defines output wavelength characteristics of visible light emitted from the gain area and adjacent gain areas comprise different wavelength locking elements.

In the head mounted display of the third further example, a first of the one or more laser chips may comprise wavelength locking elements defining different output wavelength characteristics of red visible light, a second of the one or more laser chips may comprise wavelength locking elements defining different output wavelength characteristics of green visible light and a third of the one or more laser chips may comprise wavelength locking elements defining different output wavelength characteristics of blue visible light. In other variations, there may be different combinations of colors, e.g. red, green, blue and yellow or any combination of two or more colors from red, green, blue and yellow.

A fourth further example provides a laser chip comprising a plurality of gain areas, each gain area comprising a grating-based wavelength locking element that defines a central wavelength of visible light emitted from the gain area and wherein wavelength locking element of each gain area defines a different central wavelength.

In the laser chip of the fourth further example, each of the central wavelengths is in a same visible color band.

The laser chip of the fourth further example further comprises a front facet and a rear facet, wherein each of the gain areas extend between the front facet and the rear facet and wherein the wavelength locking elements are located proximate to the front facet.

In the laser chip of the fourth further example, the wavelength locking elements extend substantially over an entire length of the gain areas.

Any range or device value given herein may be extended or altered without losing the effect sought, as will be apparent to the skilled person.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

The operations of the methods described herein may be carried out in any suitable order, or simultaneously where appropriate. Additionally, individual blocks may be deleted from any of the methods without departing from the scope of the subject matter described herein. Aspects of any of the examples described above may be combined with aspects of any of the other examples described to form further examples without losing the effect sought.

The term ‘comprising’ is used herein to mean including the method blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the scope of this specification.

What is claimed is:

1. A laser chip comprising a plurality of gain areas, each gain area comprising a ridge waveguide and a wavelength locking element, wherein each wavelength locking element defines output wavelength characteristics of visible light emitted from the gain area and adjacent gain areas comprise different wavelength locking elements.

2. The laser chip according to claim 1, wherein each of the plurality of gain areas comprises a different wavelength locking element, such that for each gain area, the output wavelength characteristics of visible light emitted from the gain area is different.

3. The laser chip according to claim 2, wherein the output wavelength characteristics of visible light emitted from each gain area are offset by a predefined amount.

4. The laser chip according to claim 1, wherein the wavelength locking element in each gain area is proximate to a front facet of the gain area.

5. The laser chip according to claim 1, wherein the wavelength locking element in each gain area extends over substantially the entire length of the gain area.

6. The laser chip according to claim 1, wherein the wavelength locking element in each gain area is proximate to a rear facet of the laser chip.

7. The laser chip according to claim 1, wherein the wavelength locking element is a grating-based structure.

8. The laser chip according to claim 7, wherein the grating-based structure comprises a chirped grating.

9. The laser chip according to claim 1, further comprising an integrally formed combiner section, the combiner section comprising a plurality of input waveguides, each input waveguide coupled to the ridge waveguide in one of the gain areas and a single output waveguide.

10. The laser chip according to claim 1, further comprising an integrally formed gain/modulation section, the gain/modulation section comprising a plurality of waveguides, each waveguide coupled to the ridge waveguide in one of the gain areas.

11. The laser chip according to claim 1, further comprising an integrally formed combiner section and an integrally formed gain/modulation section, the combiner section comprising a plurality of input waveguides, each input waveguide coupled directly or indirectly to the ridge waveguide in one of the gain areas and a single output waveguide.

12. The laser chip according to claim 11, wherein each input waveguide in the combiner section is coupled to the ridge waveguide in one of the gain areas via the gain/modulation section.

13. The laser chip according to claim 1, comprising four gain areas.

14. The laser chip according to claim 1, wherein the ridge waveguides in each of the plurality of gain areas are parallel to each other.

15. A head mounted display comprising one or more laser chips, each laser chip comprising a plurality of gain areas, each gain area comprising a ridge waveguide and a wavelength locking element, wherein each wavelength locking element defines output wavelength characteristics of visible light emitted from the gain area and adjacent gain areas comprise different wavelength locking elements.

16. The head mounted display according to claim 15, wherein a first of the one or more laser chips comprises wavelength locking elements defining different output wavelength characteristics of red visible light, a second of the one or more laser chips comprises wavelength locking elements defining different output wavelength characteristics of green visible light and a third of the one or more laser chips comprises wavelength locking elements defining different output wavelength characteristics of blue visible light.

17. A laser chip comprising a plurality of gain areas, each gain area comprising a grating-based wavelength locking element that defines a central wavelength of visible light emitted from the gain area and wherein wavelength locking element of each gain area defines a different central wavelength.

18. The laser chip of claim 17, wherein each of the central wavelengths is in a same visible color band.

19. The laser chip of claim 17, further comprising a front facet and a rear facet, wherein each of the gain areas extend between the front facet and the rear facet and wherein the wavelength locking elements are located proximate to the front facet.

20. The laser chip of claim 19, wherein the wavelength locking elements extend substantially over an entire length of the gain areas.
